(19) United States
(12) Patent Application Publication
(10) Pub. No.: US 2023/0167020 A1
(43) Pub. Date: Jun. 1, 2023

(54) GLASS-BASED ARTICLES WITH REDUCED RISK OF DELAYED FAILURE AND HIGH STORED STRAIN ENERGY

(71) Applicant: CORNING INCORPORATED, CORNING, NY (US)

(72) Inventors: Jason Thomas Harris, Horseheads, NY (US); Kevin Barry Reiman, Horseheads, NY (US)

(21) Appl. No.: 18/071,125

(22) Filed: Nov. 29, 2022

Related U.S. Application Data
(60) Provisional application No. 63/284,297, filed on Nov. 30, 2021.

(51) Int. Cl. C03C 21/00; H05K 5/03; C03C 10/00

(52) U.S. Cl. CPC C03C 21/002; H05K 5/03; C03C 10/0027; C03C 2204/00

(57) ABSTRACT

A glass-based article comprising a thickness t; a first clad layer having a first thickness t_{C1}; a second clad layer having a first thickness t_{C2}; and a core layer having a first thickness tₒ, which core layer is disposed between and bonded to the first and second clad layers. A first compressive stress region extends from a surface of the first clad layer to a first depth of compression DOC₁. A second compressive stress region extends from a surface of the second clad layer to a second depth of compression DOC₂. The first and second compressive stress regions comprise a maximum compressive stress greater than or equal to 500 MPa. A central tension region extends from DOC₁ to DOC₂ and has a maximum central tension CT greater than or equal to 250 MPa. A difference in flaw sizes that produce delayed fracture is less than or equal to 3 μm.

### CROSS-REFERENCE TO RELATED APPLICATIONS

This application claims the benefit of priority under 35 U.S.C. § 119 of U.S. Provisional Application Ser. No. 63/284,297 filed on Nov. 30, 2021 the content of which is relied upon and incorporated herein by reference in its entirety.

### BACKGROUND

### Field

The present specification generally relates to glass-based articles with high stored strain energy and a reduced risk of delayed failure.

### Technical Background

The mechanical strength of pristine glasses, such as optical fiber, is extremely high (GPa range) but the strength of everyday glass products such as windows and bottles is significantly lower (MPa range) primarily due to the presence of pre-existing surface flaws. It has been known that these glasses can be made mechanically stronger and more wear-resistant by forming a compressive stress layer on the surface of the glass. It has been long recognized that is desirable when improving the mechanical performance of glass to have a surface compressive stresses (CS) which prevents flaw/crack nucleation and/or growth. It is not only the magnitude of compression, but also the depth of the compressive stress (DOC) into the glass surface, that must be considered. It is desirable to achieve both a high surface compression and a deep depth of compression in the same glass article.

There are two popular approaches to produce a compressive surface stress on a glass surface, thermal tempering and ion-exchange. In order to thermally temper a glass, a glass product is heated to near the softening temperature and then quenched. As a result, the glass will possess a lower surface temperature than the interior temperature during cooling. This temperature difference is maintained until the surface of the glass cools to room temperature. As the center of the glass also cools, more slowly, to room temperature it will contract to a smaller specific volume while the high specific volume of the surface layer remains unchanged. This leads to a surface compressive layer that gives tempered glass its strength. This process is commonly used to strengthen automobile side and rear windows.

A second popular strengthening method, ion-exchange (IOX) or chemical tempering is limited in applicability to glasses containing mobile cations. In this method, glasses containing alkali ions, e.g. Na+, are treated in a molten salt containing larger alkali ions, e.g. K+, at a temperature below the glass transition temperature. Although alkali ions rest in specific positions within the rigid glass network, they possess the ability to jump between sites. As a result, when an alkali-containing glass is immersed in a molten salt containing another type of larger alkali ions, some larger ions from the molten salt will exchange with those in the outer layers of the glass. If this process is performed at a temperature below the glass transition temperature, such that stress relaxation is sluggish compared to the rate of ion-exchange, large ions will find themselves stuffed into rigid sites that are too small. Since the structure cannot relax to accommodate the newly acquired larger ions, a biaxial compressive stress is formed. This process, sometimes called ion-stuffing or chemical tempering, can produce a surface layer with a high compressive stress on the glass and is commonly employed to strengthen products such as aircraft windows and scratch resistant cover glasses on electronic devices.

High stored energy strengthened glass articles may fragment into many pieces, and can create dangerous shards and/or eject particles, upon failure. So-called parabolic stress profiles with a high surface compressive stress values and high central tension values are attractive due to the high degree of strengthening provided to the glass and the resistance to fracture. However, such high stored energy stress profiles can result in an inconvenient and potentially dangerous delayed fracture behavior.

Accordingly, a need exists for strengthened glass articles that provide the benefits of high stored energy stress profiles with a reduced propensity for delayed fracture.

### SUMMARY

According to aspect (1), a glass-based article is provided. The glass-based article comprises: a thickness t; a first clad layer having a first thickness t_{C1}; a second clad layer having a first thickness t_{C2}; a core layer having a first thickness tₒ, wherein the core layer is disposed between and bonded to the first clad layer and the second clad layer; a first compressive stress region extending from a surface of the first clad layer to a first depth of compression DOC₁, the first compressive stress region comprising a first maximum compressive stress CS₁ greater than or equal to 500 MPa; a second compressive stress region extending from a surface of the second clad layer to a second depth of compression DOC₂, the second compressive stress region comprising a second maximum compressive stress CS₂ greater than or equal to 500 MPa; and a central tension region extending from DOC₁ to DOC₂, comprising a maximum central tension CT greater than or equal to 250 MPa, wherein a difference in flaw sizes that produce delayed fracture is less than or equal to 3 μm.

According to aspect (2), the glass-based article of aspect (1) is provided, wherein the first compressive stress region comprises a parabolic stress profile.

According to aspect (3), the glass-based article of any of aspect (1) to the preceding aspect is provided, wherein t_{C1} is greater than or equal to 100 μm.

According to aspect (4), the glass-based article of any of aspect (1) to the preceding aspect is provided, wherein t_{C1} is greater than or equal to 0.2t.

According to aspect (5), the glass-based article of any of aspect (1) to the preceding aspect is provided, wherein t_{C1}=t_{C2}.

According to aspect (6), the glass-based article of any of aspect (1) to the preceding aspect is provided, wherein t_{C1}+t_{C2}+tₒ=t.

According to aspect (7), the glass-based article of any of aspect (1) to the preceding aspect is provided, wherein DOC₁ is greater than or equal to 0.2t.

According to aspect (8), the glass-based article of any of aspect (1) to the preceding aspect is provided, wherein the stress at a depth of DOC₁-2 μm is greater than or equal to 40 MPa greater than the stress at a depth of DOC₁+2 μm.

According to aspect (9), the glass-based article of any of aspect (1) to the preceding aspect is provided, wherein the stress at a depth of DOC₁-2 μm is greater than or equal to 100 MPa greater than the stress at a depth of DOC₁+2 μm.

According to aspect (10), the glass-based article of any of aspect (1) to the preceding aspect is provided, wherein a stress profile of the glass-based article has a slope discontinuity at DOC₁.

According to aspect (11), the glass-based article of any of aspect (1) to the preceding aspect is provided, wherein t is less than or equal to 2 mm.

According to aspect (12), the glass-based article of any of aspect (1) to the preceding aspect is provided, wherein t is greater than or equal to 0.2 mm.

According to aspect (13), the glass-based article of any of aspect (1) to the preceding aspect is provided, wherein the first clad layer and the second clad layer comprise a lithium aluminosilicate.

According to aspect (14), the glass-based article of any of aspect (1) to the preceding aspect is provided, wherein the first clad layer and the second clad layer are formed from the same glass composition.

According to aspect (15), the glass-based article of any of aspect (1) to the preceding aspect is provided, wherein the first clad layer and the core layer have substantially matched alkali ion diffusivity and diffusivity network dilation.

According to aspect (16), the glass-based article of any of aspect (1) to the preceding aspect is provided, wherein the first clad layer has a first coefficient of thermal expansion CTE₁ and the core layer has a core coefficient of thermal expansion CTEₒ, and CTE₁<CTEₒ.

According to aspect (17), the glass-based article of any of aspect (1) to the preceding aspect is provided, wherein the first clad layer has a first diffusivity network dilation and the core layer has a core diffusivity network dilation, and the first diffusivity network dilation is greater than the core diffusivity network dilation.

According to aspect (18), a consumer electronic product is provided. The consumer electronic product comprises: a housing comprising a front surface, a back surface and side surfaces; electrical components at least partially within the housing, the electrical components comprising a controller, a memory, and a display, the display at or adjacent the front surface of the housing; and a cover substrate disposed over the display, wherein at least a portion of at least one of the housing and the cover substrate comprises the glass-based article of any of aspect (1) to the preceding aspect.

According to aspect (19), a method is provided. The method comprises: forming a step-type stress profile in a glass-based substrate to form a strengthened glass-based substrate; and ion exchanging the strengthened glass-based substrate to form a glass-based article, wherein the glass-based article comprises: a thickness t; a first clad layer having a first thickness t_{C1}; a second clad layer having a first thickness t_{C2}; a core layer having a first thickness tₒ, wherein the core layer is disposed between and bonded to the first clad layer and the second clad layer; a first compressive stress region extending from a surface of the first clad layer to a first depth of compression DOC₁, the first compressive stress region comprising a first maximum compressive stress CS₁ greater than or equal to 500 MPa; a second compressive stress region extending from a surface of the second clad layer to a second depth of compression DOC₂, the second compressive stress region comprising a second maximum compressive stress CS₂ greater than or equal to 500 MPa; and a central tension region extending from DOC₁ to DOC₂, comprising a maximum central tension CT greater than or equal to 250 MPa, wherein a difference in flaw sizes that produce delayed fracture is less than or equal to 3 μm.

According to aspect (20), the method of aspect (19) is provided, wherein forming the step-type stress profile comprises thermal tempering.

According to aspect (21), the method of any of aspect (19) to the preceding aspect is provided, wherein the first compressive stress region comprises a parabolic stress profile.

According to aspect (22), the method of any of aspect (19) to the preceding aspect is provided, wherein t_{C1} is greater than or equal to 100 μm.

According to aspect (23), the method of any of aspect (19) to the preceding aspect is provided, wherein t_{C1} is greater than or equal to 0.2t.

According to aspect (24), the method of any of aspect (19) to the preceding aspect is provided, wherein t_{C1}=t_{C2}.

According to aspect (25), the method of any of aspect (19) to the preceding aspect is provided, wherein t_{C1}+t_{C2}+tₒ=t.

According to aspect (26), the method of any of aspect (19) to the preceding aspect is provided, wherein DOC₁ is greater than or equal to 0.2t.

According to aspect (27), the method of any of aspect (19) to the preceding aspect is provided, wherein the stress at a depth of DOC₁-2 μm is greater than or equal to 40 MPa greater than the stress at a depth of DOC₁+2 μm.

According to aspect (28), the method of any of aspect (19) to the preceding aspect is provided, wherein the stress at a depth of DOC₁-2 μm is greater than or equal to 1001 MPa greater than the stress at a depth of DOC₁+2 μm.

According to aspect (29), the method of any of aspect (19) to the preceding aspect is provided, wherein a stress profile of the glass-based article has a slope discontinuity at DOC₁.

According to aspect (30), the method of any of aspect (19) to the preceding aspect is provided, wherein t is less than or equal to 2 mm.

According to aspect (31), the method of any of aspect (19) to the preceding aspect is provided, wherein t is greater than or equal to 0.2 mm.

According to aspect (32), the method of any of aspect (19) to the preceding aspect is provided, wherein the first clad layer and the second clad layer comprise a lithium aluminosilicate.

According to aspect (33), the method of any of aspect (19) to the preceding aspect is provided, wherein the first clad layer and the second clad layer are formed from the same glass composition.

According to aspect (34), the method of any of aspect (19) to the preceding aspect is provided, wherein the first clad layer and the core layer have substantially matched alkali ion diffusivity and diffusivity network dilation.

According to aspect (35), the method of any of aspect (19) to the preceding aspect is provided, wherein the first clad layer has a first coefficient of thermal expansion CTE₁ and the core layer has a core coefficient of thermal expansion CTEₒ, and CTE₁<CTEₒ.

According to aspect (36), the method of any of aspect (19) to the preceding aspect is provided, wherein the first clad layer has a first diffusivity network dilation and the core layer has a core diffusivity network dilation, and the first diffusivity network dilation is greater than the core diffusivity network dilation.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a cross section of a glass-based article having compressive stress regions according to embodiments described and disclosed herein;

FIG. 2A is a plan view of an exemplary electronic device incorporating any of the glass-based articles disclosed herein;

FIG. 2B is a perspective view of the exemplary electronic device of FIG. 2A;

FIG. 3 is a schematic cross-section of a glass-based article according to an embodiment;

FIG. 4 is a plot of crack velocity as a function of applied stress intensity factor for various glass compositions;

FIG. 5 is a plot of stress intensity factor as a function of flaw size for a comparative glass-based article with a parabolic stress profile;

FIG. 6 is a plot of stress intensity factor as a function of flaw size for comparative glass-based articles with a parabolic stress profile and different thicknesses;

FIG. 7 is a plot of stress intensity factor as a function of flaw size for a comparative glass-based article with a parabolic stress profile, and two glass-based articles with stress profiles according to embodiments; and

FIG. 8 is a plot of time to failure as a function of flaw size for a comparative glass-based article with a parabolic stress profile, and a glass-based article with a stress profile according to an embodiment.

### DETAILED DESCRIPTION

Reference will now be made in detail to strengthened glass-based articles according to various embodiments. The stress profiles of the strengthened glass-based articles have a high degree of stored energy and have a reduced flaw size range that may result in delayed fracture.

As used herein, a trailing 0 in a number is intended to represent a significant digit for that number. For example, the number “1.0” includes two significant digits, and the number “1.00” includes three significant digits.

As utilized herein, a “glass substrate” refers to a glass piece that has not been ion exchanged. Similarly, a “glass article” refers to a glass piece that has been ion exchanged and is formed by subjecting a glass substrate to an ion exchange process. A “glass-based substrate” and a “glass-based article” are defined accordingly and include glass substrates and glass articles as well as substrates and articles that are made wholly or partly of glass, such as glass substrates that include a surface coating or glass-ceramic substrates. While glass substrates and glass articles may generally be referred to herein for the sake of convenience, the descriptions of glass substrates and glass articles should be understood to apply equally to glass-based substrates and glass-based articles.

The glass-based articles described herein have stress profiles adapted to provide the benefits of a parabolic stress profile while exhibiting a reduced likelihood of a delayed fracture. As utilized herein, a delayed fracture refers to a fracture that occurs in time range greater than or equal to 10⁻² minutes (6 seconds) to less than or equal to 10⁴ minutes (about 17 hours) after the introduction of a flaw. Delayed fracture is produced by the sub-critical growth of flaws, and sub-critical flaw growth is generally produced by a specific flaw size range for a given stress profile. The stress profiles described herein reduce the flaw size range that is capable of producing delayed fracture.

The stress profiles of the glass-based articles described herein have a high rate of increase in the tensile stress beyond the depth of compression. The rapid increase in the tensile stress produces a rapid increase in the stress intensity factor of flaws at depths around the DOC, limiting the flaw depths that will be capable of sub-critical growth and delayed fracture.

To address the problem of delayed failures a stress profile that combines the features of a parabolic stress profile and a laminate stress profile is provided. A laminate stress profile as utilized herein refers to a step-type stress profile, with compression on the outer clad layers that is balanced by tension in the core layer. At the interface between the clad layers and the core layers defines the depth of compression and is a nearly step change in stress, from peak compression to peak tension. This step-change feature generates a rapid increase in stress intensity factor when cracks enter into the tension region. The rapid increase in the stress intensity factor reduces the flaw size range that is capable of producing delayed fracture when compared to a parabolic stress profile alone.

The glass-based articles have a reduced flaw size range that may result in delayed fracture. The flaw size range that produces delayed fracture may be defined as the difference between the flaw size that will cause fracture at a time of 10⁻² minutes and the flaw size that will cause fracture at a time of 10⁴ minutes, referred to herein as the difference in flaw sizes. In embodiments, the difference in flaw sizes that produce delayed fracture is less than or equal to 3 μm, such as less than or equal to 2.5 μm, less than or equal to 2 μm, less than or equal to 1.5 μm, less than or equal to 1 μm, or less. The low difference in flaw sizes that produce delayed fracture of the glass-based articles described herein reduces the likelihood that a give flaw will fall within the range, reducing the chances for delayed fracture.

The parabolic stress profiles described herein are advantageous for providing fracture resistance against large flaws, such as those produced by high impact sharp contact events. In embodiments, the parabolic stress profile may be of the type described in U.S. Patent Application Publication No. 2016/0102014, which is incorporated herein by reference in its entirety. The glass-based articles may include a parabolic stress profile in the first compressive stress region, the second compressive stress region, the central tension region, or all regions.

The stress profile of the glass-based articles described herein is additive, including the features of the step-type stress profile and the parabolic stress profile. For example, the step-type profile is added to the parabolic stress profile, shifting the parabolic stress profile to higher stresses in the compressive stress region and increasing tension in the central tension region. The additive stress profile includes the discontinuity of the step-type profile at the depth of compression, and the depth of compression may be located at the clad-core transition.

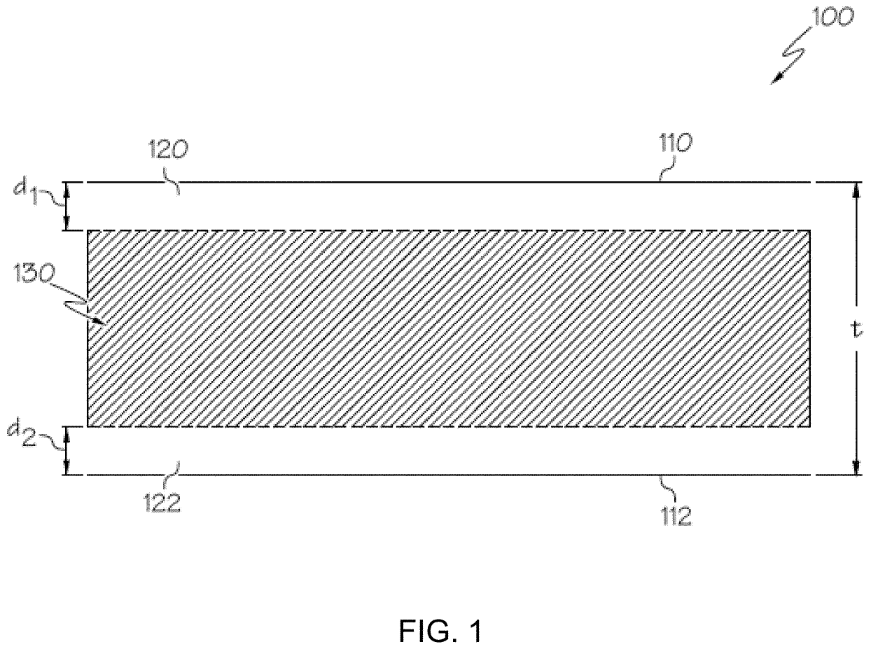

As mentioned above, in embodiments, the glass-based articles described herein are strengthened, such as by ion exchange, making a glass-based article that is damage resistant for applications such as, but not limited to, display covers. With reference to FIG. 1, a glass-based article is depicted that has a first region under compressive stress (e.g., first and second compressive layers 120, 122 in FIG. 1) extending from the surface to a depth of compression (DOC) of the glass-based article and a second region (e.g., central region 130 in FIG. 1) under a tensile stress or central tension (CT) extending from the DOC into the central or interior region of the glass-based article. As used herein, DOC refers to the depth at which the stress within the glass-based article changes from compressive to tensile. At the DOC, the stress crosses from a positive (compressive) stress to a negative (tensile) stress and thus exhibits a stress value of zero.

According to the convention normally used in the art, compression or compressive stress is expressed as a negative (<0) stress and tension or tensile stress is expressed as a positive (>0) stress. Throughout this description, however, CS is expressed as a positive or absolute value—i.e., as recited herein, CS=|CS|. The compressive stress (CS) has a maximum at or near the surface of the glass-based article, and the CS varies with distance d from the surface according to a function. Referring again to FIG. 1, a first segment 120 extends from first surface 110 to a depth d₁ and a second segment 122 extends from second surface 112 to a depth dz. Together, these segments define a compression or CS of glass-based article 100. The surface compressive stress (CS) may be measured using a scattered light polariscope (SCALP) technique known in the art.

The compressive stress of both major surfaces (110, 112 in FIG. 1) is balanced by stored tension in the central region (130) of the glass-based article. The surface compressive stress (CS), maximum central tension (CT) and DOC values may be measured using a scattered light polariscope (SCALP) technique known in the art. The SCALP method also may be used to determine the stress profile of the glass-based articles.

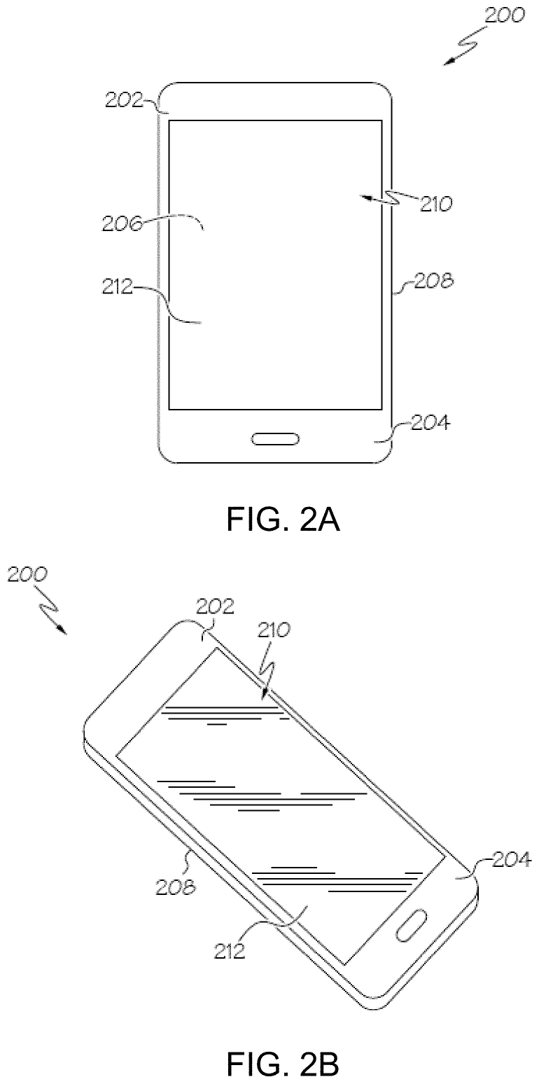

The glass-based articles disclosed herein may be incorporated into another article such as an article with a display (or display articles) (e.g., consumer electronics, including mobile phones, tablets, computers, navigation systems, and the like), architectural articles, transportation articles (e.g., automobiles, trains, aircraft, sea craft, etc.), appliance articles, or any article that requires some transparency, scratch-resistance, abrasion resistance or a combination thereof. An exemplary article incorporating any of the glass-based articles disclosed herein is shown in FIGS. 2A and 2B. Specifically, FIGS. 2A and 2B show a consumer electronic device 200 including a housing 202 having front 204, back 206, and side surfaces 208; electrical components (not shown) that are at least partially inside or entirely within the housing and including at least a controller, a memory, and a display 210 at or adjacent to the front surface of the housing; and a cover 212 at or over the front surface of the housing such that it is over the display. In embodiments, at least a portion of at least one of the cover 212 and the housing 202 may include any of the glass-based articles described herein.

In embodiments, the CS of the glass-based articles is from greater than or equal to 500 MPa to less than or equal to 2000 MPa, such as greater than or equal to 600 MPa to less than or equal to 1900 MPa, greater than or equal to 700 MPa to less than or equal to 1800 MPa, greater than or equal to 800 MPa to less than or equal to 1700 MPa, greater than or equal to 900 MPa to less than or equal to 1300 MPa, greater than or equal to 1000 MPa to less than or equal to 1200 MPa, greater than or equal to 500 MPa to less than or equal to 1100 MPa, and all ranges and sub-ranges between the foregoing values.

The measurement of a maximum CT value is an indicator of the total amount of stress stored in the strengthened articles. For this reason, the ability to achieve higher CT values correlates to the ability to achieve higher degrees of strengthening. In embodiments, the glass-based article may have a maximum CT greater than or equal to 250 MPa, or more.

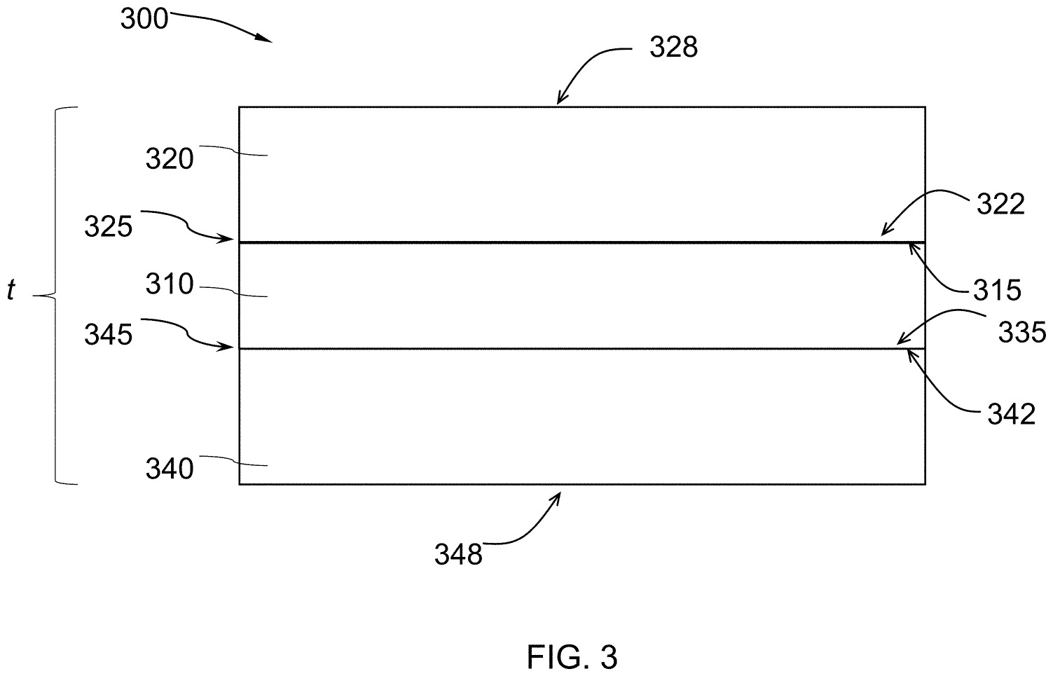

FIG. 3 illustrates a schematic cross-section of a glass-based article 300 having a thickness (t) and at least three layers, the article comprising a glass-based core layer 310, a first clad layer 320, and a second clad layer 340. The glass-based core layer 310 has a first surface 315 and a second surface 335. The first clad layer 320 has a third surface 322 directly bonded to the first surface 315 to provide a first core-clad interface 325; the first clad layer 320 also has a fourth surface 328. The second clad layer 340 has a fifth surface 342 directly bonded to the second surface 335 to provide a second core-clad interface 345; the second clad layer 340 also has a sixth surface 348. According to one or more embodiments, the core layer 310 is bonded to the first clad layer 320 and the second clad layer 340 without a polymer or adhesive between the core layer 310 and the first clad layer 320 or between the core layer 310 and the second clad layer 340. According to one or more embodiments, the layers are directly bonded to each other.

The glass-based article 300 is shown having a thickness (t), which is the thickness of the final article upon lamination of the layers and any thermal and/or chemical treatment. The core layer 310 has a thickness tₒ, the first clad layer 320 has a thickness t_{C1}, and the second clad layer 340 has a thickness t_{C2}. The nominal thickness of the glass-based article 300 is the sum of t_{c1}, t_{c2}, and tₒ. In one or more embodiments, the glass-based article of any embodiment disclosed herein has a thickness in a range of greater than or equal to 0.2 mm to less than or equal to 2 mm, such as greater than or equal to 0.3 mm to less than or equal to 1 mm, greater than or equal to 0.4 mm to less than or equal to 0.9 mm, greater than or equal to 0.5 mm to less than or equal to 0.8 mm, greater than or equal to 0.6 mm to less than or equal to 0.7 mm, and any and all sub-ranges formed between any of the foregoing endpoints.

In embodiment, the first clad layer 320 has a thickness t_{C1} that is at greater than or equal to 0.2t, such as greater than or equal to 0.21t, greater than or equal to 0.22t, greater than or equal to 0.23t, greater than or equal to 0.24t, greater than or equal to 0.25t, or any values or sub-ranges therebetween. The first clad layer 320 may have a thickness t_{C1} greater than or equal to 100 microns, such as greater than or equal to 200 microns, greater than or equal to 300 microns, greater than or equal to 400 microns, or any values or sub-ranges therebetween. Generally, the first clad layer is a different thickness than the core layer (t_{C1}≠tₒ); in a specific embodiment, the first clad layer is thicker than the sheet forming the core substrate (t_{C1}>tₒ). The second clad layer may be approximately the same thickness as the first clad layer, or the same as the first clad layer (t_{C1}=t_{C2}), in which case a symmetrical article is formed. As a result, the thickness of the second clad layer may be any of the thicknesses described herein for the first clay layer.

The first clad layer 320 may comprise a first glass composition and the core layer 310 may comprise a second glass composition, wherein the first glass composition is different from the second glass composition. In embodiments, the first glass composition has a first alkali ion diffusivity and the second glass composition has a second alkali ion diffusivity, and the first ion diffusivity and second ion diffusivity are different. In embodiments, the first glass composition has a first alkali ion diffusivity and the second glass composition has a second alkali ion diffusivity, and the first ion diffusivity and second ion diffusivity are substantially matched or the same. For example, the first clad layer and the core layer may have a substantially matched alkali ion diffusivity. Such matched alkali ion diffusivity aids in the achievement of the desired parabolic stress profile by ion exchange.

In embodiments, the first glass composition has a first diffusivity network dilation and the second glass composition has a second diffusivity network dilation, and the first diffusivity network dilation and second diffusivity network dilation are substantially matched or the same. For example, the first clad layer and the core layer may have a substantially matched diffusivity network dilation. Such matched diffusivity network dilation aids in the achievement of the desired parabolic stress profile by ion exchange. In embodiments, the first clad layer has a first diffusivity network dilation and the core layer has a core diffusivity network dilation, and the first diffusivity network dilation may be greater than the core diffusivity network dilation. The mismatched diffusivity network dilation properties may allow the formation of a step-type stress profile.

In embodiments, the first glass composition has a first coefficient of thermal expansion (CTE₁) and the second glass composition has a second coefficient of thermal expansion (CTEₒ), and CTE₁ and CTEₒ are different. In embodiments, CTE₁ is lower than the CTEₒ to impart a compressive stress in the first clad layer and the second clad layer. Stated differently, the first clad layer has a first coefficient of thermal expansion (CTE₁) and the core layer has a core coefficient of thermal expansion (CTEₒ), and in embodiments CTE₁<CTEₒ.

In embodiments, the sheet that forms the second clad layer may comprise the same chemical composition as the first clad layer, in which case a symmetrical article is formed. In embodiments, the sheet that forms the second clad layer may comprise a third chemical composition that is different from the first and second chemical compositions, in which case an asymmetrical article is formed. Thus, the sheet that forms the second clad layer may have approximately the same or the same CTE as the sheet that forms the first clad layer; or the sheet that forms the second clad layer may have a different CTE than the sheet that forms the first clad layer. In embodiments, one or more additional clad layers are bonded to a surface of the first clad layer, the second clad layer, or both.

The first clad layer and the second clad layer may be formed from the same glass composition. In embodiments, the first and/or second clad layer include an alkali aluminosilicate glass. In a preferred embodiment, the first and second clad layers include a lithium aluminosilicate glass.

As noted above, DOC is measured using a scattered light polariscope (SCALP) technique known in the art. The DOC of the first clad layer DOC₁ is located at the transition between the first clad layer and the core layer. The DOC of the second clad layer DOC₂ is located at the transition between the second clad layer and the core layer. In embodiments, DOC₁ is the same as DOC₂, when measured from the closest major surfaces, respectively. Additionally, DOC₁ may be the same as the thicknesses of the first clad layer described herein, and DOC₂ may be the same as the thicknesses of the second clad layer described herein.

The DOC may be described as a portion of the thickness (t) of the glass-based article. High DOC values provide improved resistance to fracture, especially for situations where deep flaws may be introduced. In embodiments, DOC₁ is greater than or equal to 0.2t, such as greater than or equal to 0.21t, greater than or equal to 0.22, greater than or equal to 0.23t, greater than or equal to 0.24t, greater than or equal to 0.25t, or more. In embodiments, DOC₂ is greater than or equal to 0.2t, such as greater than or equal to 0.21t, greater than or equal to 0.22, greater than or equal to 0.23t, greater than or equal to 0.24t, greater than or equal to 0.25t, or more.

As described above, the stress profiles described herein may have a discontinuity at DOC₁. Similarly, the stress profiles described herein may have a discontinuity at DOC₂. A discontinuity may be indicated by a large and substantially instantaneous change in the stress value at the DOC. The change in stress at the DOC may be substantially equivalent to or equivalent to the difference between the stress difference between the compressive stress region and the central tension region attributable to the step-type stress profile. The difference between the stress at a depth of DOC₁-2 μm and the stress at a depth of DOC₁+2 μm may be greater than or equal to 40 MPa, such as greater than or equal to 50 MPa, greater than or equal to 60 MPa, greater than or equal to 70 MPa, greater than or equal to 80 MPa, greater than or equal to 90 MPa, greater than or equal to 100 MPa, greater than or equal to 110 MPa, greater than or equal to 120 MPa, greater than or equal to 130 MPa, greater than or equal to 140 MPa, greater than or equal to 150 MPa, or more.

The time to fracture of the glass-based articles may be modeled to determine the likelihood of delayed failure and the associated flaw size range. The model simulates a plane strain geometry with a crack of variable length. The stress profiles are explicitly applied to the models. After application of the stress profile, the stress intensity factor for the flaw was calculated. An exponential function was fit to experimental data for the non-strengthened glass article and the predicted fatigue life as a function of crack length was calculated according to the equation:

$$T = {\int }_{{K}_{I}}^{{K}_{IC}} \frac{\frac{d K}{d a}}{m {e}^{n K}} d K$$

where T is the time to failure, K_{IC} is the fracture toughness, K_{I} is the stress intensity factor for the initial flaw, a is the flaw length, m and n are parameters from the fit of the experimental data, and K is the stress intensity factor.

As utilized herein, the fracture toughness refers to the K_{IC} value as measured by the chevron notched short bar method unless otherwise noted. The chevron notched short bar (CNSB) method utilized to measure the K_{IC} value is disclosed in Reddy, K. P. R. et al, “Fracture Toughness Measurement of Glass and Ceramic Materials Using Chevron-Notched Specimens,” J. Am. Ceram. Soc., 71 [6], C-310-C-313 (1988) except that Y*ₘ is calculated using equation 5 of Bubsey, R. T. et al., “Closed-Form Expressions for Crack-Mouth Displacement and Stress Intensity Factors for Chevron-Notched Short Bar and Short Rod Specimens Based on Experimental Compliance Measurements,” NASA Technical Memorandum 83796, pp. 1-30 (October 1992). Additionally, the K_{IC} values are measured on non-strengthened glass samples, such as measuring the K_{IC} value prior to ion exchanging a glass-based substrate to form a glass-based article.

The glass-based articles described herein may be formed by any appropriate method. In embodiments, a step-type stress profile is formed in a glass-based substrate to form a strengthened glass-based substrate. The formation of the step-type stress profile may include thermal tempering. The strengthened glass-based substrate may then be ion exchanged to form a glass-based article, and the glass-based article may include a parabolic stress profile.

The glass-based substrates utilized to form the glass-based article are laminates. The laminates may be produced by fusion bonding the clad and core layers. Fusion bonding may be achieved according to the process described in U.S. Pat. No. 9,522,836 or in a temperature-controlled oven. With fusion bonding, the sheets are put into contact in a fusion draw or oven at temperature above the softening point of the materials. The glass-based materials effectively fuse after controlled cooling to form a uniform laminate with induced stress based on the different mechanical properties of the sheets. The fusion bonding process may directly impart a step-type stress profile to the glass-based substrate without the need for additional thermal treatments. For fusion bonding, a laminate fusion draw apparatus may be used to form a laminated glass article, where the apparatus includes an upper isopipe which is positioned over a lower isopipe. The upper isopipe includes a trough into which a molten cladding material composition is fed from a melter. Similarly, the lower isopipe includes a trough into which a molten glass-based core composition is fed from a glass melter.

The parabolic stress profile may be formed in the glass by exposing the glass to an ion exchange medium. In embodiments, the ion exchange medium may be molten salt bath, such as a bath containing a molten nitrate salt. In embodiments, the ion exchange medium may be a molten salt bath including KNO₃, NaNO₃, or combinations thereof. In embodiments, other sodium and potassium salts may be used in the ion exchange medium, such as, for example sodium or potassium nitrites, phosphates, or sulfates. In embodiments, the ion exchange medium may include lithium salts, such as LiNO₃. The ion exchange medium may additionally include additives commonly included when ion exchanging glass, such as silicic acid. The ion exchange process is applied to a glass-based substrate to form a glass-based article of the type described herein.

The ion exchange process may include a second ion exchange treatment. In embodiments, the second ion exchange treatment may include ion exchanging the glass-based article in a second molten salt bath. The second ion exchange treatment may utilize any of the ion exchange mediums described herein. In embodiments, the second ion exchange treatment utilizes a second molten salt bath that includes KNO₃.

After an ion exchange process is performed, it should be understood that a composition at the surface of an ion exchanged glass-based article is be different than the composition of the as-formed glass substrate (i.e., the glass substrate before it undergoes an ion exchange process). This results from one type of alkali metal ion in the as-formed glass substrate, such as, for example Li⁺ or Na⁺, being replaced with larger alkali metal ions, such as, for example Na⁺ or K⁺, respectively. However, the glass composition at or near the center of the depth of the glass-based article will, in embodiments, still have the composition and microstructure of the as-formed non-ion exchanged glass substrate utilized to form the glass-based article. As utilized herein, the center of the glass-based article refers to any location in the glass-based article that is a distance of at least 0.5t from every surface thereof, where t is the thickness of the glass-based article.

### Examples

Embodiments will be further clarified by the following examples. It should be understood that these examples are not limiting to the embodiments described above.

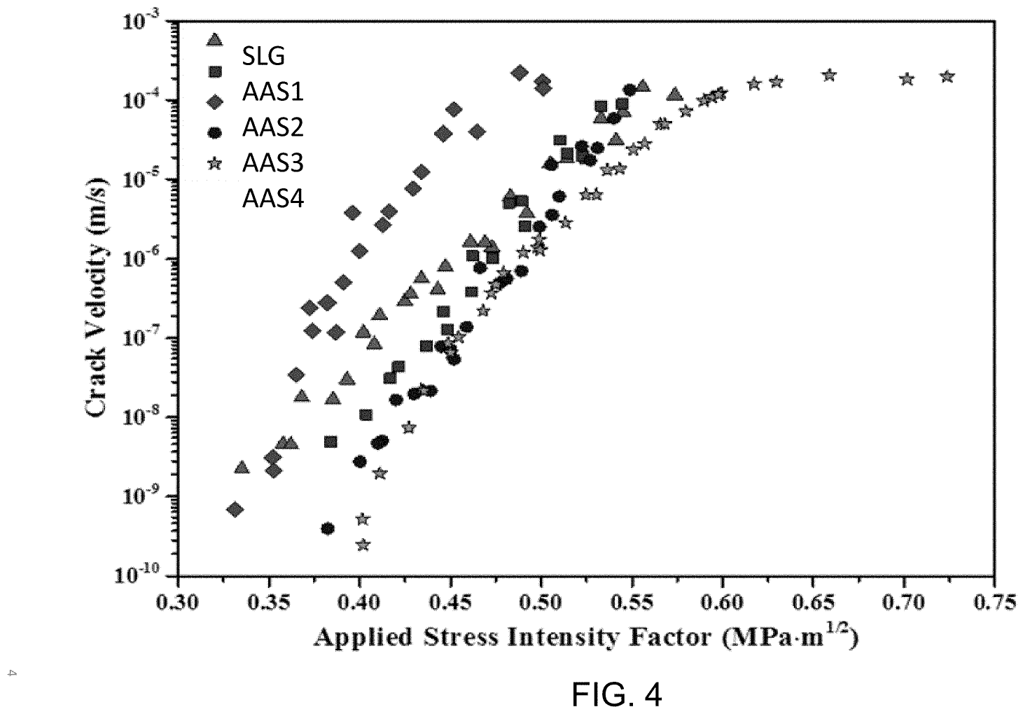

Crack velocity as a function of applied stress intensity factor was measured for a variety of glasses, including a soda lime glass (SLG) and various alkali aluminosilicate glasses. FIG. 4 shows the experimentally measured crack velocities.

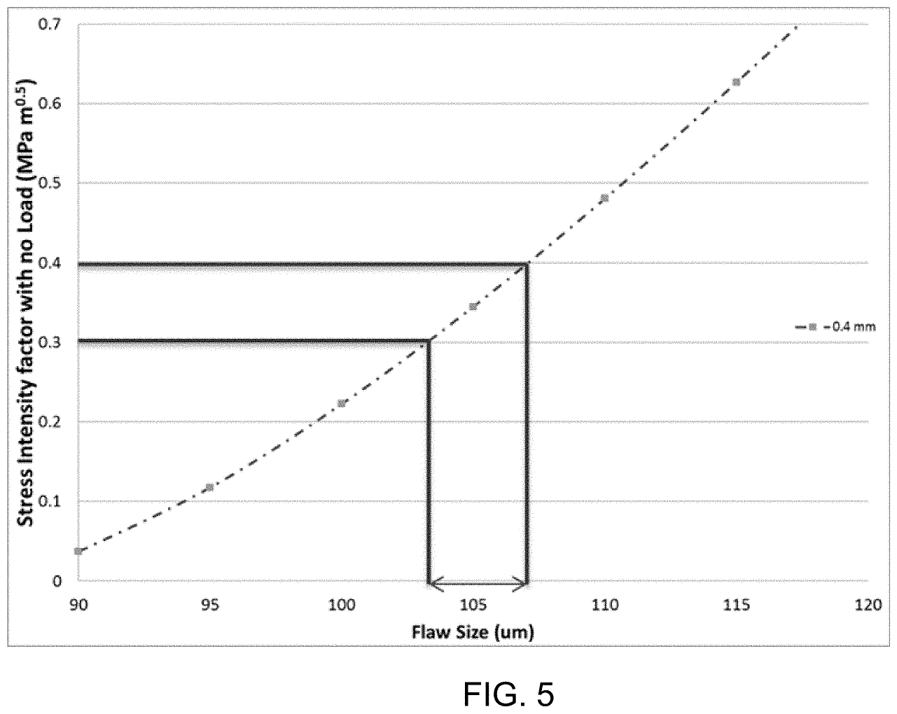

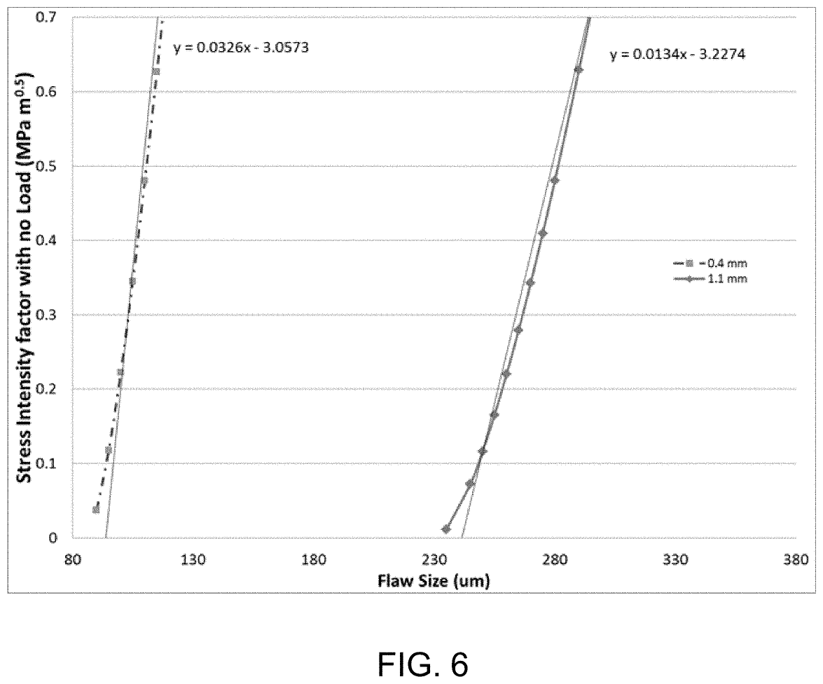

Based on the measurements in FIG. 4, the stress intensity factor was modeled as a function of crack length for a 0.4 mm thick article with a parabolic stress profile and a surface compressive stress of 500 MPa. The delayed fracture range was assigned to the stress intensity factor values of 0.3-0.4 MPa·m^{0.5}. As shown in FIG. 5, the flaw size range that may produce delayed fracture was about 5 μm. A 1.1 mm thick article with a parabolic stress profile and a surface compressive stress of 500 MPa was also modeled. As shown in FIG. 6, the thicker article produced a larger flaw size range that will produce delayed fracture.

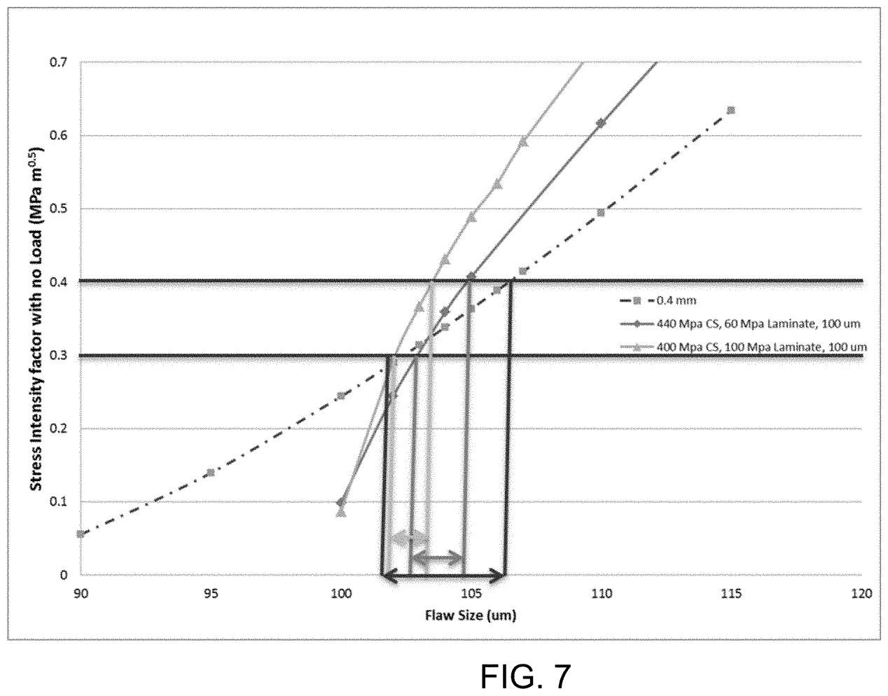

Stress profiles of the type described herein were modeled and compared to a 0.4 mm thick article with a parabolic stress profile and a surface compressive stress of 500 MPa. A first exemplary stress profile for a 0.4 mm thick article had a surface compressive stress of 500 MPa, with 440 MPa attributable to a parabolic profile and 60 MPa attributable to a step-type stress profile produced by the laminate. A second exemplary stress profile for a 0.4 mm thick article had a surface compressive stress of 500 MPa, with 400 MPa attributable to a parabolic profile and 100 MPa attributable to a step-type stress profile produced by the laminate. The exemplary stress profiles were modeled on a three-layer laminate where the first and second clad layers had a thickness of 100 μm. As shown in FIG. 7, the addition of the step-type stress profile reduced the flaw size range that is capable of producing delayed failure, with higher levels of stress attributable to the step-type stress profile decreasing the flaw size range. The comparative parabolic only stress profile had a difference in flaw sizes of about 7 μm, the first exemplary stress profile had a difference in flaw sizes of about 3 μm, and the second exemplary stress profile had a difference in flaw sizes of about 2 μm.

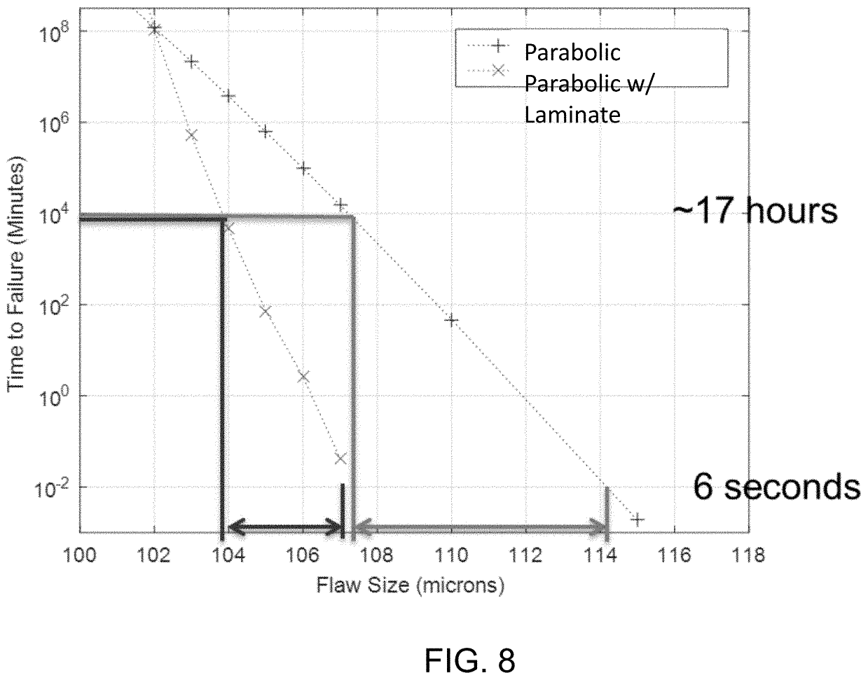

Based on the above modeled results and an exponential relationship between crack velocity as a function of crack stress intensity factor, the fatigue life as a function of flaw length has been predicted. As shown in FIG. 8, the stress profiles described herein reduces the range of flaw sizes for which delayed fracture can occur by more than half when compared to a parabolic profile with the same surface compressive stress.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A glass-based article, comprising:
a thickness t;
a first clad layer having a first thickness t_{C1};
a second clad layer having a first thickness t_{C2};
a core layer having a first thickness tₒ, wherein the core layer is disposed between and bonded to the first clad layer and the second clad layer;
a first compressive stress region extending from a surface of the first clad layer to a first depth of compression DOC₁, the first compressive stress region comprising a first maximum compressive stress CS₁ greater than or equal to 500 MPa;
a second compressive stress region extending from a surface of the second clad layer to a second depth of compression DOC₂, the second compressive stress region comprising a second maximum compressive stress CS₂ greater than or equal to 500 MPa; and
a central tension region extending from DOC₁ to DOC₂, comprising a maximum central tension CT greater than or equal to 250 MPa,
wherein a difference in flaw sizes that produce delayed fracture is less than or equal to 3 μm.

2. The glass-based article of claim 1, wherein the first compressive stress region comprises a parabolic stress profile.

3. The glass-based article of claim 1, wherein t_{C1} is greater than or equal to 0.2t.

4. The glass-based article of claim 1, wherein DOC₁ is greater than or equal to 0.2t.

5. The glass-based article of claim 1, wherein a stress at a depth of DOC₁-2 μm is greater than or equal to 40 MPa greater than a stress at a depth of DOC₁+2 μm.

6. The glass-based article of claim 1, wherein a stress profile of the glass-based article has a slope discontinuity at DOC₁.

7. The glass-based article of claim 1, wherein t is greater than or equal to 0.2 mm and less than or equal to 2 mm.

8. The glass-based article of claim 1, wherein the first clad layer and the second clad layer comprise a lithium aluminosilicate.

9. The glass-based article of claim 1, wherein the first clad layer and the core layer have substantially matched alkali ion diffusivity and diffusivity network dilation.

10. The glass-based article of claim 1, wherein the first clad layer has a first coefficient of thermal expansion CTE₁ and the core layer has a core coefficient of thermal expansion CTEₒ, and CTE₁<CTEₒ.

11. The glass-based article of claim 1, wherein the first clad layer has a first diffusivity network dilation and the core layer has a core diffusivity network dilation, and the first diffusivity network dilation is greater than the core diffusivity network dilation.

12. A consumer electronic product, comprising:
a housing comprising a front surface, a back surface and side surfaces;
electrical components at least partially within the housing, the electrical components comprising a controller, a memory, and a display, the display at or adjacent the front surface of the housing; and
a cover substrate disposed over the display,
wherein at least a portion of at least one of the housing and the cover substrate comprises the glass-based article of claim 1.

13. A method, comprising:
forming a step-type stress profile in a glass-based substrate to form a strengthened glass-based substrate; and
ion exchanging the strengthened glass-based substrate to form a glass-based article,
wherein the glass-based article comprises:
a thickness t;
a first clad layer having a first thickness t_{C1};
a second clad layer having a first thickness t_{C2};
a core layer having a first thickness tₒ, wherein the core layer is disposed between and bonded to the first clad layer and the second clad layer;
a first compressive stress region extending from a surface of the first clad layer to a first depth of compression DOC₁, the first compressive stress region comprising a first maximum compressive stress CS₁ greater than or equal to 500 MPa;
a second compressive stress region extending from a surface of the second clad layer to a second depth of compression DOC₂, the second compressive stress region comprising a second maximum compressive stress CS₂ greater than or equal to 500 MPa; and
a central tension region extending from DOC₁ to DOC₂, comprising a maximum central tension CT greater than or equal to 250 MPa,
wherein a difference in flaw sizes that produce delayed fracture is less than or equal to 3 μm.

14. The method of claim 13, wherein the first compressive stress region comprises a parabolic stress profile.

15. The method of claim 13, wherein t_{C1} is greater than or equal to 0.2t.

16. The method of claim 13, wherein DOC₁ is greater than or equal to 0.2t.

17. The method of claim 13, wherein a stress at a depth of DOC₁-2 μm is greater than or equal to 40 MPa greater than a stress at a depth of DOC₁+2 μm.

18. The method of claim 13, wherein a stress profile of the glass-based article has a slope discontinuity at DOC₁.

19. The method of claim 13, wherein the first clad layer has a first coefficient of thermal expansion CTE₁ and the core layer has a core coefficient of thermal expansion CTEₒ, and CTE₁<CTEₒ.

20. The method of claim 13, wherein the first clad layer has a first diffusivity network dilation and the core layer has a core diffusivity network dilation, and the first diffusivity network dilation is greater than the core diffusivity network dilation.
